(19) United States
(12) Patent Application Publication
(10) Pub. No.: US 2021/0336163 A1
(43) Pub. Date: Oct. 28, 2021

(54) FLEXIBLE ARRAY SUBSTRATE, DISPLAY PANEL, AND MANUFACTURING METHOD

(71) Applicant: Wuhan China Star Optoelectronics Semiconductor Display Technology Co., LTD., Wuhan, Hubei (CN)

(72) Inventor: Sihang BAI, Wuhan, Hubei (CN)

(73) Assignee: Wuhan China Star Optoelectronics Semiconductor Display Technology Co., LTD., Wuhan, Hubei (CN)

(21) Appl. No.: 16/485,438

(22) PCT Filed: Jun. 13, 2019
(86) PCT No.: PCT/CN2019/091089

§ 371 Date: Aug. 12, 2019

(30) Foreign Application Priority Data
Jan. 30, 2019 (CN) 201910093586.3

(51) Int. Cl. H01L 51/00; H01L 51/56; H01L 27/32

(52) U.S. Cl. CPC H01L 51/0097; H01L 27/3246; H01L 51/56

(57) ABSTRACT

A flexible array substrate, a display panel, and a manufacturing method are provided. The disclosure has advantages that in a bending area, a thickness of a material layer below a metal trace is reduced, and a thickness of the material layer above the metal trace is increased, which facilitates to adjust the metal trace to a neutral surface, and improves a bending resistance and stability of the metal trace.

### FIELD OF DISCLOSURE

The present disclosure relates to the field of display devices, and in particular, to a flexible array substrate, a display panel, and a manufacturing method.

### BACKGROUND

As display screens become more widely used, widescreen technologies have become an important technical item. At the same time, the technologies of display panels with narrow borders are become more and more important. Advanced electronic products, especially hand-held electronic products, are increasingly oriented toward a narrow border design.

In order to increase a screen-to-body ratio of electronic products, a non-display area of the display panel is compressed smaller and smaller. Methods of compressing the non-display area may be to set a shaped area at an upper end of the display area, and a front camera and an earpiece of the mobile phone are disposed in the shaped area. The method may also be that a part of the display panel in which a plurality of functional layers are located in the non-display area is bent to a side of the display panel opposite to a light-emitting surface thereof to realize the narrowing design of the borders of the display panel. For example, in order to achieve the narrow border design for a small-sized mobile phone and to achieve a larger screen-to-body ratio of the mobile phone, industries have attempted to reduce a lower border area. A most effective way to reduce the lower border is a bending technology, that is, a part of the fan-out area of the screen, a driver integrated circuit (IC), and a flexible circuit board (FPC) are bent together to a backside of the screen for bonding. It can effectively reduce a length of the lower border area.

A metal trace in the bending area is subjected to a large stress, which is prone to breakage and the like, resulting in display abnormality. Therefore, the metal trace needs to have bending resistance. In an existing structural design, the bending resistance of the metal trace cannot meet the demand. Accordingly, it is particularly important to improve the bending resistance of the metal trace in the bending area.

### SUMMARY OF DISCLOSURE

The technical problem to be solved by the present disclosure is to provide a flexible array substrate, a display panel, and a manufacturing method, which can improve a bending resistance and stability of a metal trace in a bending area.

In order to solve the above problems, the present disclosure provides a flexible array substrate, includes a flexible substrate and a functional layer disposed on the flexible substrate, wherein a surface of the functional layer is covered with an organic film layer; the flexible array substrate is divided into a non-bending area and a bending area; the flexible substrate, the functional layer, and the organic film layer extend from the non-bending area to the bending area; in the bending area, the functional layer comprises a via hole, the via hole extends through the functional layer; at least one metal trace is disposed on an inner wall of the via hole; and the organic film layer fills the via hole.

In one embodiment, the inner wall of the via hole is stepped, and the metal trace extends along the stepped inner wall.

In one embodiment, a thickness of the organic film layer in the bending area is greater than a thickness of the organic film layer in the non-bending area.

In one embodiment, a height of an upper surface of the organic film layer in the bending area to the flexible substrate is greater than a height of an upper surface of the organic film layer in the non-bending area to the flexible substrate.

In one embodiment, a thickness of the flexible substrate in the bending area is less than a thickness of the flexible substrate in the non-bending area.

In one embodiment, the flexible substrate comprises a first flexible sub-substrate, an inorganic layer, and a second flexible sub-substrate; the functional layer is disposed on the second flexible sub-substrate; and in the bending area, the first flexible sub-substrate comprises a recess recessed toward the inorganic layer, such that the thickness of the flexible substrate in the bending area is less than the thickness of the flexible substrate in the non-bending area.

The present disclosure also provides a manufacturing method of the above flexible array substrate, including: providing a flexible substrate, wherein the flexible substrate is divided into a non-bending area and a bending area; forming a functional layer on the flexible substrate, wherein the functional layer extends from the non-bending area to the bending area; forming a source hole and a drain hole in the non-bending area, and forming a via hole extending through the functional layer in the bending area; forming a source and drain in the source hole and the drain hole, and forming at least one metal trace on an inner wall of the via hole; and forming an organic film layer on surfaces of the functional layer, the source, the drain, and the metal trace, wherein the organic film layer fills the via hole.

In one embodiment, in the step of forming the via hole extending through the functional layer in the bending area, at different heights of the functional layer, different widths of the functional layer are removed, such that the inner wall of the via hole is stepped.

In one embodiment, before the step of providing a flexible substrate, the method further comprises: providing a supporting substrate; forming an inorganic material block on the supporting substrate; covering a flexible substrate on the supporting substrate and the inorganic material block, wherein an area of the flexible substrate corresponding to the inorganic material block is the bending area, and an area other than the bending area is the non-bending area; and removing the supporting substrate and the inorganic material block after forming the organic film layer, such that a thickness of the flexible substrate in the bending area is less than a thickness of the flexible substrate in the non-bending area.

The present disclosure also provides a display panel including the above flexible array substrate.

In one embodiment, the inner wall of the via hole is stepped, and the metal trace extends along the stepped inner wall.

In one embodiment, a thickness of the organic film layer in the bending area is greater than a thickness of the organic film layer in the non-bending area.

In one embodiment, a height of an upper surface of the organic film layer in the bending area to the flexible substrate is greater than a height of an upper surface of the organic film layer in the non-bending area to the flexible substrate.

In one embodiment, a thickness of the flexible substrate in the bending area is less than a thickness of the flexible substrate in the non-bending area.

In one embodiment, the display panel further comprises a luminous layer; the luminous layer is disposed on the organic film layer of the flexible array substrate; the luminous layer comprises a pixel definition layer and a pillar layer; and the pixel definition layer and the pillar layer extend from the non-bending area to the bending area.

The present disclosure has advantages that in the bending area, the thickness of a material layer below the metal trace is reduced, and the thickness of the material layer above the metal trace is increased, which facilitates an adjustment of the metal trace to a neutral surface, thereby improving a bending resistance and stability of the metal trace.

### BRIEF DESCRIPTION OF DRAWINGS

FIG. 1 is a schematic diagram of a flexible array substrate of an embodiment of the present disclosure.

FIG. 2 is a flowchart showing steps of a manufacturing method of a flexible array substrate of an embodiment of the present disclosure.

FIG. 3A to FIG. 3F are schematic diagrams of a manufacturing method of a flexible array substrate of an embodiment of the present disclosure.

FIG. 4A to FIG. 4C are schematic diagrams showing a process of a flexible substrate of an embodiment of the present disclosure.

FIG. 5 is a schematic diagram of a display panel of an embodiment of the present disclosure.

### DETAILED DESCRIPTION

Specific embodiments of a flexible array substrate, a display panel, and a manufacturing method provided by the present disclosure are described in detail below with reference to accompanying drawings.

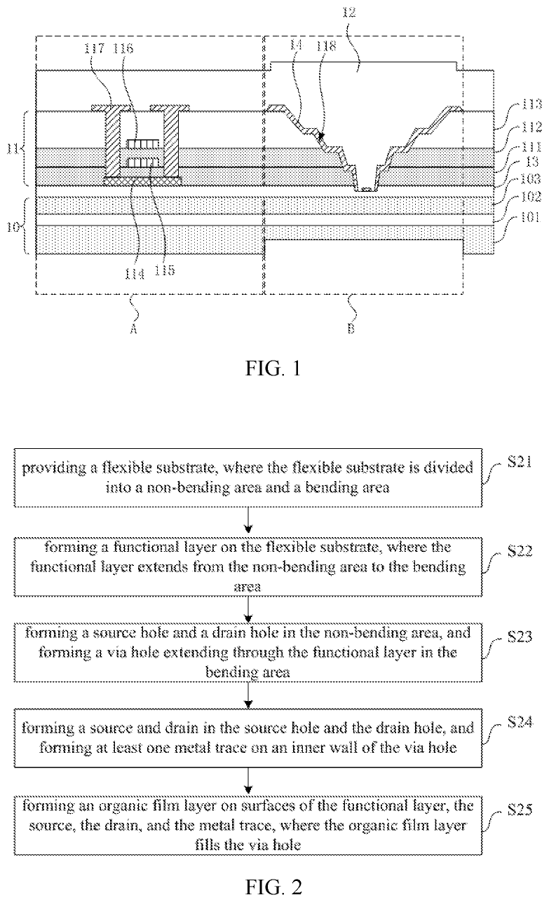

FIG. 1 is a schematic diagram of a flexible array substrate of an embodiment of the present disclosure. Please refer to FIG. 1, a flexible array substrate of the present disclosure includes a flexible substrate 10 and a functional layer 11 disposed on the flexible substrate 10. A surface of the functional layer 11 is covered with an organic film layer 12. The flexible array substrate is divided into a non-bending area A and a bending area B. The non-bending area A refers to an area that does not need to be bent, and the bending area B refers to an area that needs to be bent. The flexible substrate 10, the functional layer 11, and the organic film layer 12 extend from the non-bending area A to the bending area B. That is, the flexible substrate 10, the functional layer 11, and the organic film layer 12 are also divided into the non-bending area and the bending area.

The flexible substrate 10 may be a conventional flexible substrate such as a polyimide flexible substrate. Alternatively, the flexible substrate 10 is a composite flexible substrate. In this embodiment, the flexible substrate 10 is a composite flexible substrate, which includes a first flexible sub-substrate 101, an inorganic layer 102, and a second flexible sub-substrate 103. The functional layer 11 is disposed on the second flexible sub-substrate 103. The first flexible sub-substrate 101 includes, but is not limited to, a polyimide substrate. The inorganic layer 102 includes, but is not limited to, a silicon dioxide layer. The second flexible sub-substrate 103 includes, but is not limited to, a polyimide substrate. Furthermore, in the present embodiment, a surface of the flexible substrate 10 is covered with a buffer layer 13, which is a conventional structure. In other embodiments, the buffer layer 13 may not be provided.

The functional layer 11 includes, but is not limited to, a thin film transistor layer. Specifically, in the embodiment, the functional layer 11 includes a first gate insulating layer 111, a second gate insulating layer 112, and a passivation layer 113. The first gate insulating layer 111, the second gate insulating layer 112, and the passivation layer 113 extend from the non-bending area A to the bending area B. In the non-bending area A, an active layer 114 is further disposed between the flexible substrate 10 and the first gate insulating layer 11. A first gate 115 is further disposed between the first gate insulating layer 111 and the second gate insulating layer 112. A second gate 116 is further disposed between the second gate insulating layer 112 and the passivation layer 113. A source and a drain 117 pass through the passivation layer 113. The second gate insulating layer 112 and the first gate insulating layer 111 are connected to the active layer 114. The first gate insulating layer 111, the active layer 114, the second gate insulating layer 112, the first gate 115, the second gate 116, and the passivation layer 113 are formed the thin film transistor layer.

In the bending area B, the functional layer 11 has a via hole 118. The via hole 118 extends through the functional layer 11. Specifically, a bottom of the via hole 118 exposes an upper surface of the flexible substrate 10. In this embodiment, the via hole 118 may extend to the upper surface of the buffer layer 13 or may extends through the buffer layer 13. At least one metal trace 14 is disposed on an inner wall of the via hole 118. Specifically, the metal trace 14 extends along the inner wall of the via hole 118. Furthermore, the inner wall of the via hole 118 is stepped. The metal trace 14 extends along the stepped inner wall, which has the advantage that the stepped structure can make the inner wall of the via hole 118 be gentle, thereby ensuring that the metal trace 14 does not have a risk of disconnection during the extending process. The metal trace 14 can serve as a connection line between the source and drain in the non-bending area A and a driving integrated circuit (not shown in the drawings).

The organic film layer 12 fills the via hole 118. Specifically, the organic film layer 12 fills the via hole 118 and covers the metal trace 14. A thickness of the organic film layer 12 in the bending area B is greater than a thickness of the organic film layer 12 in the non-bending area A. For example, in order to facilitate the subsequent process, in the non-bending area A and the bending area B, an upper surface of the organic film layer 12 is in the same plane. In the bending area B, since the organic film layer 12 further fills the via hole 118, a thickness of the organic film layer 12 in the bending area B is greater than a thickness of the organic film layer 12 of the non-bending area A.

Since the organic film layer 12 fills the via hole 118, the organic film layer 12 covers the metal trace 14. The absence of an organic material layer below the metal trace 14 can be considered to reduce a thickness of the organic film layer below the metal trace 14. Moreover, increasing a thickness of the organic film layer above the metal trace facilitates an adjustment of the metal trace 14 to a neutral plane, thereby facilitating a bending resistance and stability of the metal trace 14. The specific description of the neutral plane is as follows. When the flexible array substrate is bent, there is a neutral surface on the flexible array substrate, and the neutral plane is a critical surface that is neither subjected to tensile stress nor compressive stress during bending. Film layers on a side of the neutral surface near a convex side (i.e., an outer side of the bending area) will be subjected to the tensile stress. Film layers on another side of the neutral surface away from a convex side (i.e., an inner side of the bending area) will be subjected to the compressive stress. The closer the film is to the neutral surface, the less stress it is subjected to. In the flexible array substrate of the present disclosure, the thicknesses of the organic film layer above and below the metal trace 14 is adjusted such that the metal trace 14 is located on the neutral surface, thereby improving the bending resistance of the metal trace 14.

Furthermore, a height of an upper surface of the organic film layer 12 in the bending area B to the flexible substrate 10 is greater than a height of the upper surface of the organic film layer 12 in the non-bending area A to the flexible substrate 10, which is capable of further adjusting a position of the metal trace 14 so that it is on the neutral plane. The thickness of the flexible substrate in the bending area B is less than the thickness of the flexible substrate in the non-bending area A. Specifically, in the present embodiment, in the bending area B, the first flexible sub-substrate 101 has a recess 104 that is recessed toward the organic layer 102, such that the thickness of the flexible substrate 10 in the bending area B is less than the thickness of the flexible substrate 10 in the non-bending area A, which is capable of further adjusting a position of the metal trace 14 so that it is on the neutral plane.

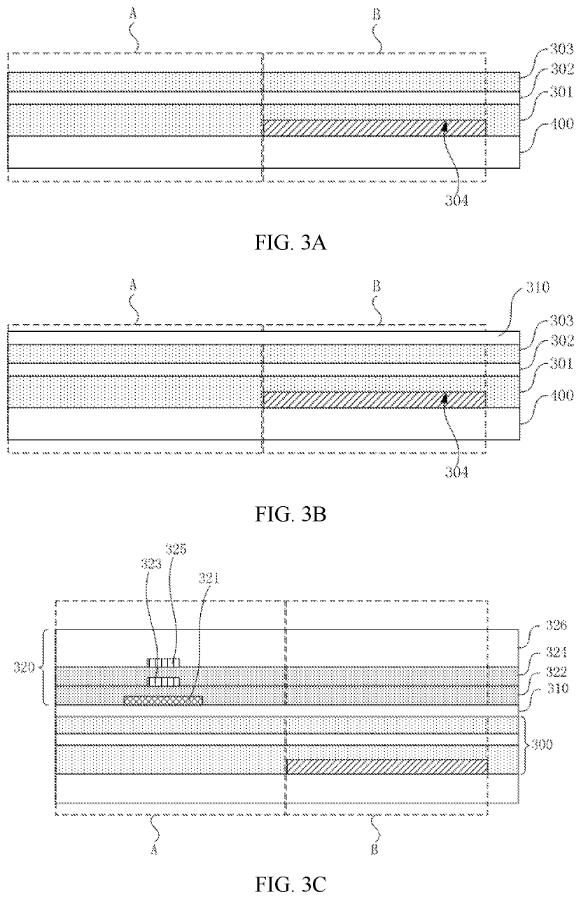

The present disclosure also provides a manufacturing method of the above flexible array substrate. FIG. 2 is a flowchart showing steps of the manufacturing method of the flexible array substrate of an embodiment of the present disclosure. Referring to FIG. 2, the manufacturing method of the flexible array substrate of the present disclosure includes the following steps. In a step S21, a flexible substrate is provided. The flexible substrate is divided into a non-bending area and a bending area. In a step S22, a functional layer is formed on the flexible substrate. The functional layer extends from the non-bending area to the bending area. In a step S23, a source hole and a drain hole are formed in the non-bending area, and a via hole extending through the functional layer is formed in the bending area. In a step S24, a source and drain are respectively formed in the source hole and the drain hole, and at least one metal trace is formed on an inner wall of the via hole. In a step S25, an organic film layer is formed on surfaces of the functional layer, the source, the drain, and the metal trace. The organic film layer fills the via hole.

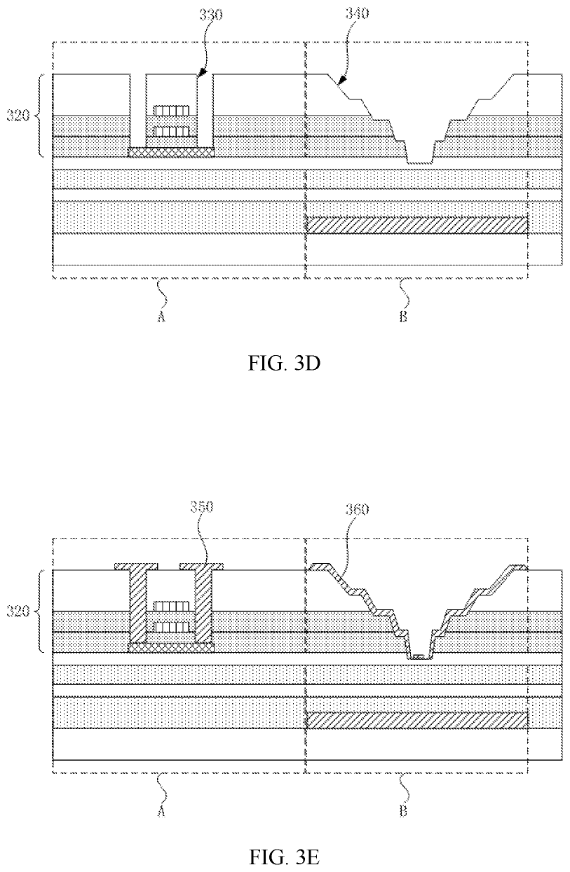

FIG. 3A to FIG. 3F are schematic diagrams of a manufacturing method of a flexible array substrate of an embodiment of the present disclosure.

Please refer to the step S21 and FIG. 3A, a flexible substrate 300 is provided. The flexible substrate 300 is divided into a non-bending area A and a bending area B. In this step, the flexible substrate 300 should to be disposed on a supporting substrate 400. The flexible substrate 300 includes, but is not limited to, a single layer substrate or a multilayer composite substrate. In this embodiment, the flexible substrate 300 is a flexible composite substrate including a first flexible sub-substrate 301, an inorganic layer 302, and a second flexible sub-substrate 303. The first flexible sub-substrate 301 has a recess 304 that is recessed toward the inorganic layer 302 such that a thickness of the flexible substrate 300 in the bending area B is less than a thickness of the flexible substrate 300 in the non-bending area A.

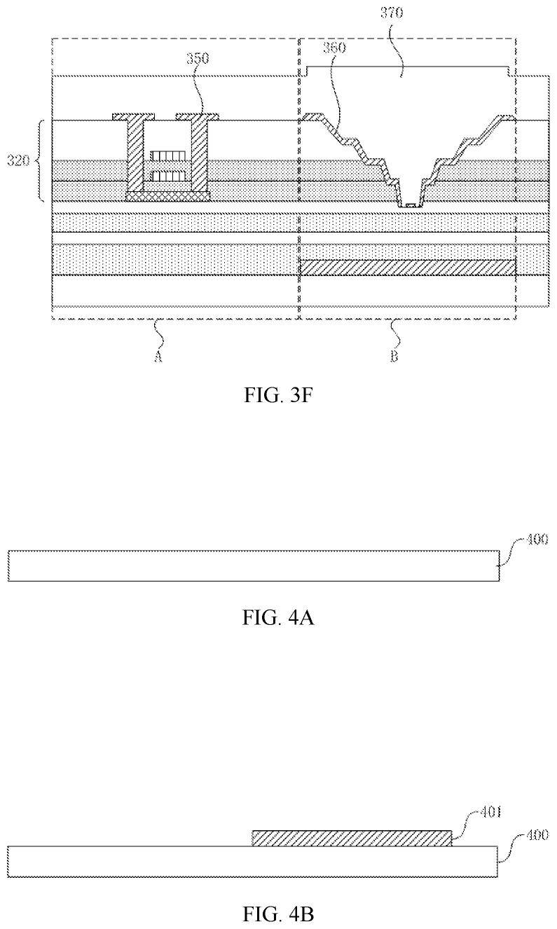

The manufacturing method of the flexible substrate 300 of the present embodiment is described below. FIG. 4A to FIG. 4C are schematic diagrams showing a process of a flexible substrate of an embodiment of the present disclosure.

Referring to FIG. 4A, the supporting substrate 400 is provided. The supporting substrate 400 includes, but is not limited to, a glass substrate.

Referring to FIG. 4B, an inorganic material block 401 is formed on the supporting substrate 400. Specifically, a layer of inorganic material having a thickness of about 1 μm, for example, a layer of silicon dioxide, is disposed on the supporting substrate 400, and the layer of inorganic material is patterned such that the inorganic material block 401 is retained only in the bending area B. The inorganic material layer may be patterned by a conventional patterning method in the art, or the organic material block 401 may be directly formed by a masking method when forming the inorganic material layer.

Referring to FIG. 4C, the first flexible sub-substrate 301 covers on the supporting substrate 400 and the inorganic material block 401. The area of the first flexible sub-substrate 301 corresponding to the inorganic material block 401 is the bending area B. The area other than the bending area B is the non-bending area A. The inorganic layer 302 and the second flexible sub-substrate 303 are sequentially deposited on the first flexible sub-substrate 301. In the bending area B, since the inorganic material block 401 occupies a partial space of the first flexible sub-substrate 301, the first flexible sub-substrate 302 forms a recess 304 that is recessed toward the inorganic layer 302, such that a thickness of the flexible substrate 300 in the bending area B is less than a thickness of the flexible substrate 300 in the non-bending area A. The supporting substrate 400 and the inorganic material block 401 should to be removed in a subsequent process to avoid affecting a bending performance of the flexible substrate.

Furthermore, after the step S21, referring to FIG. 3B, a step of forming a buffer layer 310 on the flexible substrate 300 is also included, which is an optional step. The buffer layer 310 includes, but is not limited to, a silicon dioxide layer.

Referring to step S22 and FIG. 3C, a functional layer 320 is formed on the flexible substrate 300. The functional layer 320 extends from the non-bending area A to the bending area B. Specifically, the functional layer 320 is a thin film transistor layer. In this step, an active layer 321, a first gate insulating layer 322, a first gate 323, a second gate insulating layer 324, a second gate 325, and a passivation layer 326 are sequentially formed on the flexible substrate 300. The first gate insulating layer 322, the second gate insulating layer 324, and the passivation layer 326 extend from the non-bending area A to the bending area B. In other embodiments of the present disclosure, the structure of the functional layer 302 may also be set according to actual conditions, for example, a thin film transistor layer with a single gate structure, which does not need to form two gate insulating layers. In the embodiment, the active layer 321 is disposed on the buffer layer 310.

Referring to step S23 and FIG. 3D, a source hole and a drain hole 330 are formed in the non-bending area A, and a via hole 340 extending through the functional layer 320 is formed in the bending area B. Specifically, in this step, the via hole 340 may be formed first, and the source hole and drain hole 330 may be formed sequentially. In the step of forming the via hole 340 in the bending area B, at different heights of the functional layer, different widths of the functional layer are removed, such that the inner wall of the via hole 340 is stepped. For example, at the different heights of the functional layer, the different widths of the functional layer are removed by multiple etching processes.

Referring to the step S24 and FIG. 3E, a source and a drain 350 are respectively formed in the source hole and drain hole 330, and at least one metal trace 360 is formed on the inner wall of the via hole 340. Specifically, in the step of depositing metal and patterning the metal layer, the source and the drain 350 are respectively formed in the source hole and the drain hole 330, and the metal trace 360 is formed on the inner wall of the via hole 340.

Referring to step S25 and FIG. 3F, an organic film layer 370 is formed on surfaces of the functional layer 320, the source and drain 350 and the metal trace 360. The organic film layer 370 fills the via hole 340 to form the flexible array substrate. Specifically, the organic film layer 370 may be formed using a half-tone mask process, and a thickness of the organic film layer 370 in the non-bending area A is less than a thickness of the organic film layer 370 in the bending area B. In this embodiment, an upper surface of the organic film layer 370 in the bending area B is higher than an upper surface of the organic film layer in the non-bending area A.

After the flexible array substrate is formed, if a display panel is required, a subsequent conventional process may be performed, and details are not described herein again. The supporting substrate 400 and the inorganic material block 401 can be removed after forming the display panel.

From an aspect of the manufacturing method, although the manufacturing method of the present disclosure increases a cost of the mask, it is not necessary to use an organic photoresist material under the metal trace, which reduces a risk of peeling off the organic photoresist material and metal trace, and makes it more advantageous to adjust the metal trace to the neutral surface.

The present disclosure also provides a display panel which adopts the above flexible array substrate.

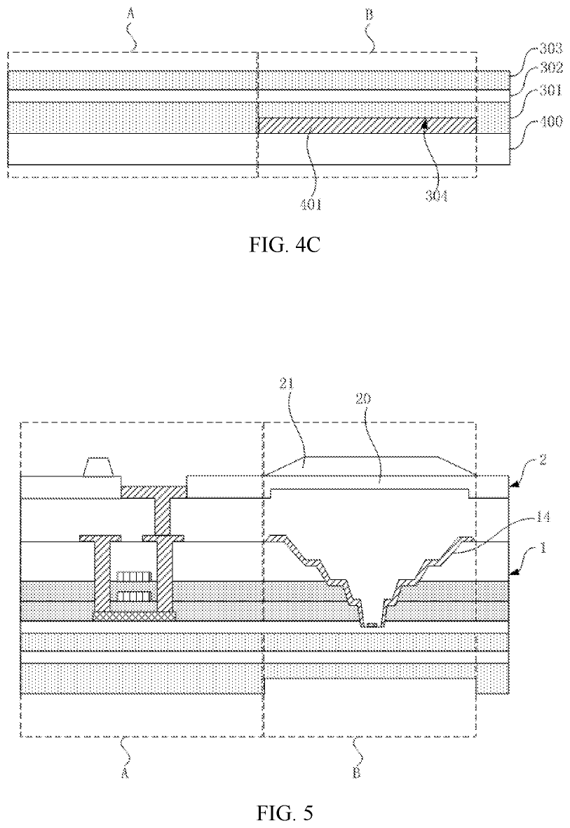

FIG. 5 is a schematic diagram of a display panel of an embodiment of the present disclosure. Referring to FIG. 5, the display panel includes the above flexible array substrate 1 and a luminous layer 2. In this embodiment, the display panel is an OLED display panel. The luminous layer 2 is disposed on the organic film layer 12 of the flexible array substrate 1. The luminous layer 2 is a conventional structure in the art. The luminous layer 2 includes a pixel definition layer 20 and a pillar layer 21, and the pixel definition layer 20 and the pillar layer 21 extend from the non-bending area A to the bending area B. That is, in the bending area B, the pixel definition layer 20 and the pillar layer 21 of the luminous layer 2 are retained, which can further increase a thickness of material layers above the metal trace 14, thereby making it easier to adjust the position of the metal trace 14 closer to the neutral plane.

The description given above is preferred embodiments of the present disclosure and it is noted that for those having ordinary skills of the art, numerous improvements and modifications can be made without departing the principles of the present invention. Such improvements and modifications are considered within the scope of protection of the present invention.

The subject matter of the present disclosure can be manufactured and used in the industry, and thus has industrial applicability.

What is claimed is:

1. A flexible array substrate, comprising a flexible substrate and a functional layer disposed on the flexible substrate, wherein a surface of the functional layer is covered with an organic film layer; the flexible array substrate is divided into a non-bending area and a bending area; the flexible substrate, the functional layer, and the organic film layer extend from the non-bending area to the bending area; in the bending area, the functional layer comprises a via hole, the via hole extends through the functional layer; at least one metal trace is disposed on an inner wall of the via hole; and the organic film layer fills the via hole.

2. The flexible array substrate as claimed in claim 1, wherein the inner wall of the via hole is stepped, and the metal trace extends along the stepped inner wall.

3. The flexible array substrate as claimed in claim 1, wherein a thickness of the organic film layer in the bending area is greater than a thickness of the organic film layer in the non-bending area.

4. The flexible array substrate as claimed in claim 1, wherein a height of an upper surface of the organic film layer in the bending area to the flexible substrate is greater than a height of an upper surface of the organic film layer in the non-bending area to the flexible substrate.

5. The flexible array substrate as claimed in claim 1, wherein a thickness of the flexible substrate in the bending area is less than a thickness of the flexible substrate in the non-bending area.

6. The flexible array substrate as claimed in claim 5, wherein the flexible substrate comprises a first flexible sub-substrate, an inorganic layer, and a second flexible sub-substrate; the functional layer is disposed on the second flexible sub-substrate; and in the bending area, the first flexible sub-substrate comprises a recess recessed toward the inorganic layer, such that the thickness of the flexible substrate in the bending area is less than the thickness of the flexible substrate in the non-bending area.

7. A manufacturing method of a flexible array substrate according to claim 1, comprising:
providing a flexible substrate, wherein the flexible substrate is divided into a non-bending area and a bending area;
forming a functional layer on the flexible substrate, wherein the functional layer extends from the non-bending area to the bending area;
forming a source hole and a drain hole in the non-bending area, and forming a via hole extending through the functional layer in the bending area;
forming a source and drain in the source hole and the drain hole, and forming at least one metal trace on an inner wall of the via hole; and
forming an organic film layer on surfaces of the functional layer, the source, the drain, and the metal trace, wherein the organic film layer fills the via hole.

8. The manufacturing method of the flexible array substrate as claimed in claim 7, wherein in the step of forming the via hole extending through the functional layer in the bending area, at different heights of the functional layer, different widths of the functional layer are removed, such that the inner wall of the via hole is stepped.

9. The manufacturing method of the flexible array substrate as claimed in claim 7, wherein before the step of providing a flexible substrate, the method further comprises:
providing a supporting substrate;
forming an inorganic material block on the supporting substrate;
covering a flexible substrate on the supporting substrate and the inorganic material block, wherein an area of the flexible substrate corresponding to the inorganic material block is the bending area, and an area other than the bending area is the non-bending area; and
removing the supporting substrate and the inorganic material block after forming the organic film layer, such that a thickness of the flexible substrate in the bending area is less than a thickness of the flexible substrate in the non-bending area.

10. A display panel as claimed in claim 1, comprising the flexible array substrate of claim 1.

11. The display panel as claimed in claim 10, wherein the inner wall of the via hole is stepped, and the metal trace extends along the stepped inner wall.

12. The display panel as claimed in claim 10, wherein a thickness of the organic film layer in the bending area is greater than a thickness of the organic film layer in the non-bending area.

13. The display panel as claimed in claim 10, wherein a height of an upper surface of the organic film layer in the bending area to the flexible substrate is greater than a height of an upper surface of the organic film layer in the non-bending area to the flexible substrate.

14. The display panel as claimed in claim 10, wherein a thickness of the flexible substrate in the bending area is less than a thickness of the flexible substrate in the non-bending area.

15. The display panel as claimed in claim 10, wherein the display panel further comprises a luminous layer; the luminous layer is disposed on the organic film layer of the flexible array substrate; the luminous layer comprises a pixel definition layer and a pillar layer; and the pixel definition layer and the pillar layer extend from the non-bending area to the bending area.
